(19) United States
(12) Patent Application Publication
(10) Pub. No.: US 2024/0324119 A1
(43) Pub. Date: Sep. 26, 2024

(54) SCREEN SPLITTER CAPABLE OF REALIZING EQUAL STRETCHING AND CLAMPING

(71) Applicant: Yuan MA, Shenzhen (CN)

(72) Inventor: Yuan MA, Shenzhen (CN)

(21) Appl. No.: 18/125,726

(22) Filed: Mar. 23, 2023

(51) Int. Cl. H05K 5/02; F16M 11/04; F16M 11/08; F16M 11/20

(52) U.S. Cl. CPC H05K 5/0217; F16M 11/041; F16M 11/08; F16M 11/2085

(57) ABSTRACT

Disclosed herein is a screen splitter capable of realizing equal stretching and clamping, including a fixed member, wherein movable members are arranged on two sides of the fixed member respectively, a second end of at least one of the movable members is rotatably connected to an auxiliary display screen, clamping portions are arranged at the second ends on the front sides of the movable members, first ends of the movable members are arranged in the fixed member and are telescopically connected to the fixed member. In the present invention, each movable member is separately and telescopically connected to the fixed member, and the telescopic portion is hidden in the fixed member; in addition, the fixed member and the movable members are telescopically connected, and the movable members extend out of the fixed member when in use; and the movable members are retracted into the fixed member when not in use.

### BACKGROUND OF THE INVENTION

The present invention relates to the technical field of screen splitters, in particular to a screen splitter capable of realizing equal stretching and clamping.

Screen splitters increase display areas of laptops, desktop computers and other displays by additionally providing auxiliary display screens, and thus it is convenient for users to carry out multi-task operations. In order to facilitate carrying, the existing laptops generally have small screens, the common screens are 14 inches or 15.6 inches, the display areas of the screens are very limited, windows need to be switched frequently during operation, or pictures are small and displayed details of the pictures are limited when contrast display is required, thus the laptops are inconvenient to use, and the use experience of users is affected. The display areas can be expanded through the screen splitters, thereby improving the use experience of the users.

The existing screen splitters are generally glued or clamped on main displays; an adhesive of the adhesive screen splitter is inconvenient to detach and is prone to aging, so that the connection is not reliable; two clamping portions of the clamping screen splitter are telescopic relatively, telescopic mechanisms are exposed, and the telescopic mechanisms are weak portions of the screen splitter structure and are prone to damage; in addition, the exposed telescopic mechanisms damage the main display easily.

The above-mentioned defects need to be overcome.

### BRIEF SUMMARY OF THE INVENTION

In order to solve the problems that an existing adhesive screen splitter is poor in connection reliability and telescopic mechanisms of a clamping screen splitter are prone to damage due to the exposure to the outside, the present invention provides a screen splitter capable of realizing equal stretching and clamping.

The technical solution of the present invention is as follows:
the screen splitter capable of realizing equal stretching and clamping comprises a fixed member, wherein movable members are arranged on two sides of the fixed member respectively, a second end of at least one of the movable members is rotatably connected to an auxiliary display screen, clamping portions are arranged at the second ends on the front sides of the movable members, first ends of the movable members are arranged in the fixed member and are telescopically connected to the fixed member, and the two movable members telescope on the fixed member so as to adjust the distance between the two clamping portions such that main display screens of different sizes can be clamped by the two clamping portions.

Further, sliding rails are arranged on the fixed member, a sliding groove slidably connected to one of the sliding rails is formed in each of the movable members, positioning columns are arranged in the sliding rail and the sliding groove respectively, a spring is arranged between the two positioning columns, and two ends of the spring are connected to the two positioning columns respectively.

Further, limiting columns are arranged on the fixed member, limiting grooves slidably connected to the limiting columns are formed in the movable members, and the length of the limiting grooves is the telescopic stroke of the movable members.

Further, a gear is rotatably connected to the fixed member, racks meshing with the gear are arranged on the movable members, the first ends of the movable members are step-shaped, and the first ends of the two movable members are staggered with each other.

Further, a clamping plate is arranged at the top of the fixed member.

Further, pads are arranged on the sides of the clamping plate and the clamping portions that are in contact with the main display screen.

Further, holding grooves are formed in the movable members, the clamping portions are hinged to the holding grooves, and the clamping portions are rotatably stored in the holding grooves or rotatably protrude out of the holding grooves.

Further, avoiding openings are formed at the positions of groove openings of the holding grooves that are far away from the hinged positions with the clamping portions, and ribs are arranged at the positions of the clamping portions that are close to the avoiding openings.

Further, a support is rotatably connected to the back of the fixed member, and the support is rotatably unfolded to support the fixed member.

Further, the support is hinged to the back of the fixed member, and the support is U-shaped.

Further, a sheath is arranged on the outer side of the top of the support.

Further, at least one expansion interface is provided on the fixed member, and the expansion interfaces are configured to be externally connected to display screens.

Further, there are two expansion interfaces on the fixed member, the fixed member can be connected to two extra external display screens by means of the two expansion interfaces, and four split screens can be achieved through combination with the two unfolded auxiliary display screens.

Further, lines of the auxiliary display screens are gathered in a bus, the lines and the bus are hidden in the fixed member, and an interface of the bus is provided on the fixed member.

The present invention according to the above-mentioned solution has the beneficial effects as follows:
1. in the present invention, the fixed member and the movable members are telescopically connected, and the movable members extend out of the fixed member when in use, thereby facilitating usage; the movable members are retracted into the fixed member when not in use, thereby reducing the size and facilitating storage; in addition, each movable member is separately and telescopically connected to the fixed member so as to enhance the structural strength of a telescopic portion, and the telescopic portion is hidden in the fixed member so as to protect the telescopic portion and the main display screen;
2. in the present invention, the auxiliary display screens are rotatably connected to the movable members, when in use, the auxiliary display screens are rotated to be unfolded, thereby facilitating adjustment according to the usage habit of a user; and when not in use, the auxiliary display screens are rotated to overlap with the fixed member, thereby reducing the length of the screen splitter and further facilitating storage;
3. in the present invention, the clamping portions are hinged to the holding grooves, and when the screen splitter is in use, the clamping portions are rotated to protrude out of the holding grooves such that the clamping portions can be clamped with side surfaces of the main display screen in a contact manner; and when the screen splitter is not in use, the clamping portions are rotated to be stored in the holding grooves, thereby facilitating storage; and
4. in the present invention, the U-shaped support is arranged at the back of the fixed member, when in use, devices such as personal digital assistants and mobile phones which need auxiliary supporting for standing can be supported by the U-shaped support, the rotation resistance between the U-shaped support and the fixed member is increased by a damping member such that it is not easy for the two to rotate relatively, the angle after adjustment can be kept, and usage is facilitated; during supporting, the friction force between the U-shaped support and a supporting table top can be increased by means of the sheath, thereby improving the supporting stability; and in addition, the U-shaped support can be used for suspending and fixing, which further improves the stability of the connected screen splitter.

### BRIEF DESCRIPTION OF THE DRAWINGS

In order to explain technical solutions in embodiments of the present invention more clearly, drawings needed in descriptions of the embodiments or the prior art will be briefly introduced below. Obviously, the accompanying drawings in the following descriptions are some embodiments of the present invention, and for those of ordinary skill in the art, other drawings can be obtained according to these accompanying drawings without involving any inventive effort.

FIG. 1 is a schematic diagram of a front structure of the present invention in a usage state;

FIG. 2 is an exploded view of the front structure of the present invention;

FIG. 3 is a schematic diagram of a back structure of the present invention;

FIG. 4 is a schematic diagram of the back structure of the present invention in the usage state;

FIG. 5 is a schematic diagram of the back structure of the present invention in a stored state;

FIG. 6 is a schematic diagram of an internal structure of a fixed member of the present invention;

FIG. 7 is an enlarged structure diagram at A in FIG. 2; and

FIG. 8 is an enlarged structure diagram at B in FIG. 2.

Reference numerals in the drawings: 1. fixed member; 101. sliding rail; 102. limiting column; 103. clamping plate; 2. movable member; 201. sliding groove; 202. limiting groove; 203. rack; 204. holding groove; 205. avoiding opening; 3. auxiliary display screen; 4. clamping portion; 401. rib; 5. positioning column; 6. spring; 7. gear; 8. pad; 9. support; and 901. sheath.

### DETAILED DESCRIPTION OF THE INVENTION

In order to make the technical problems to be solved by the present invention, the technical solutions and the beneficial effects more clear, the present invention is further described in detail in conjunction with accompanying drawings and embodiments below. It should be understood that the specific embodiments described herein are only used to explain the present invention, not to define the present invention.

It should be noted that when a component is called “fixed to” or “arranged on” or “connected to” another component, it can be directly or indirectly located on another component. The orientations or positions indicated by the terms “upper”, “lower”, “left”, “right”, “front”, “rear”, “vertical”, “horizontal”, “top”, “bottom”, “inner”, “outer” and the like are orientations or positions based on the drawings, are only for the purpose of facilitating describing, and cannot be understood as limitations on the technical solution. The terms “first”, “second” and the like are only for the purpose of facilitating describing, and cannot be understood as indicating or implying the relative importance or implicitly indicating the number of technical features. Unless otherwise specified, “a plurality of” means two or more. Unless otherwise specified, “several” means one or more.

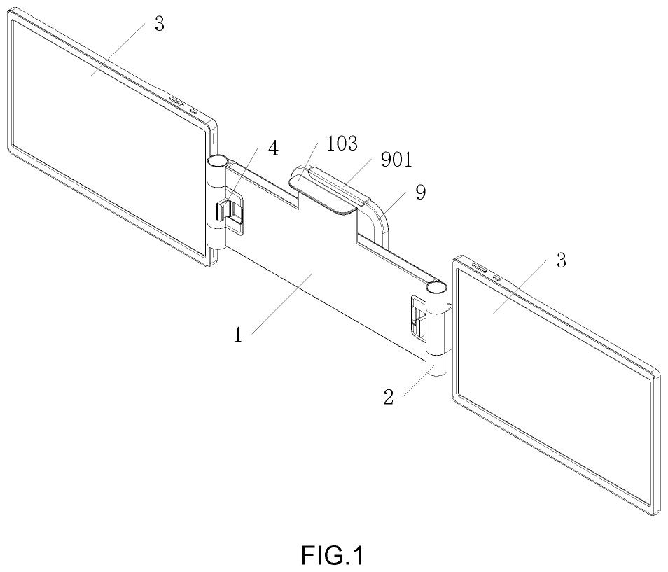

As shown in FIGS. 1-3 and FIG. 6, a screen splitter capable of realizing equal stretching and clamping in an embodiment of the present invention comprises a fixed member 1, wherein movable members 2 are arranged on two sides of the fixed member 1 respectively, and second ends of the two movable members 2 are rotatably connected to auxiliary display screens 3; first ends of the movable members 2 are telescopically connected in the fixed member 1, so that the fixed member 1 has the flat outside and can protect the first ends of the movable members 2; and clamping portions 4 are arranged at the second ends on the front sides of the movable members 2, and the clamping portions 4 on the two movable members 2 are configured to clamp two sides of a main display screen to limit the auxiliary display screens 3 on side surfaces of the main display screen.

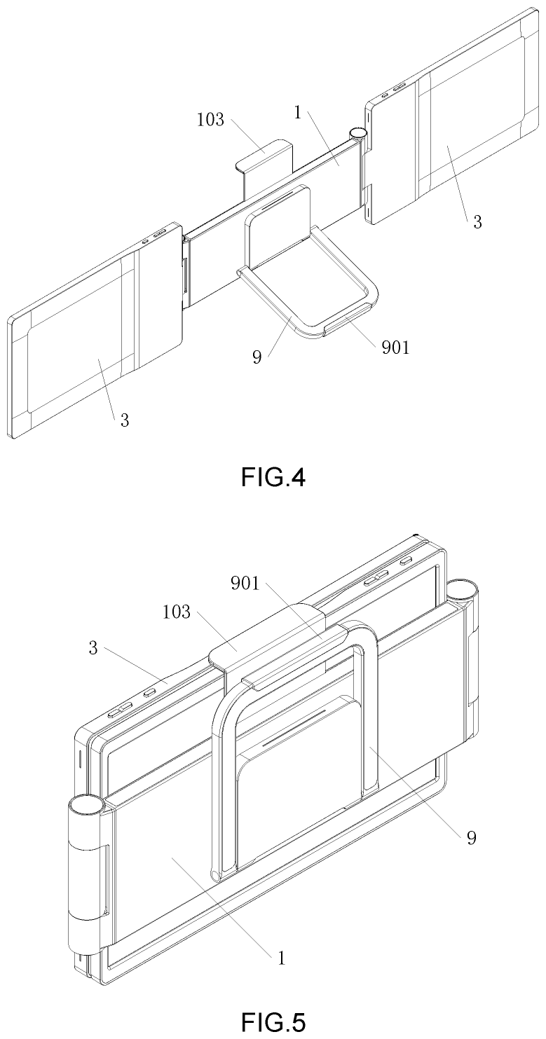

As shown in FIG. 5, when the screen splitter in this embodiment is in a stored state, the movable members 2 are retracted in the fixed member 1, and the two auxiliary display screens 3 are rotatably folded on the front side of the fixed member 1.

As shown in FIG. 1, during usage, the auxiliary display screens 3 are rotated to be unfolded to proper angles, then the movable members 2 are stretched such that the clamping portions 4 on the two movable members 2 get away from each other, when the distance between the two clamping portions 4 is greater than the width of the main display screen, the two clamping portions 4 clamp the two sides of the main display screen, and clamping is realized by means of the friction force between the movable members 2 and the fixed member 1, thereby connecting the screen splitter to the main display screen, arranging the auxiliary display screens 3 on the side surfaces of the main display screen, increasing the display area, and facilitating split display. The main display screen is generally a light and thin display screen, for example, a console display, a laptop screen, a personal digital assistant screen, a mobile phone screen and the like.

In this embodiment, the fixed member 1 and the movable members 2 are telescopically connected, and the movable members 2 extend out of the fixed member 1 when in use, thereby facilitating usage; and the movable members 2 are retracted into the fixed member 1 when not in use, thereby reducing the size and facilitating storage. The auxiliary display screens 3 are rotatably connected to the movable members 2, when in use, the auxiliary display screens 3 are rotated to be unfolded, and certain included angles are formed between the auxiliary display screens 3 and the fixed member 1 and are generally obtuse angles, thereby facilitating adjustment according to the usage habit of a user; and when not in use, the auxiliary display screens 3 are rotated to be folded on the fixed member 1, thereby overlapping the auxiliary display screens 3 with the fixed member 1, reducing the length of the screen splitter and further facilitating storage.

In the actual application process of the present invention, the second end of at least one of the movable member 2 is rotatably connected to the auxiliary display screen 3, there are generally two auxiliary display screens 3, the auxiliary display screen 3 may also be rotatably arranged on the fixed member 1, and the display screen can be rotated to be folded on the front side or the back side of the fixed member 1.

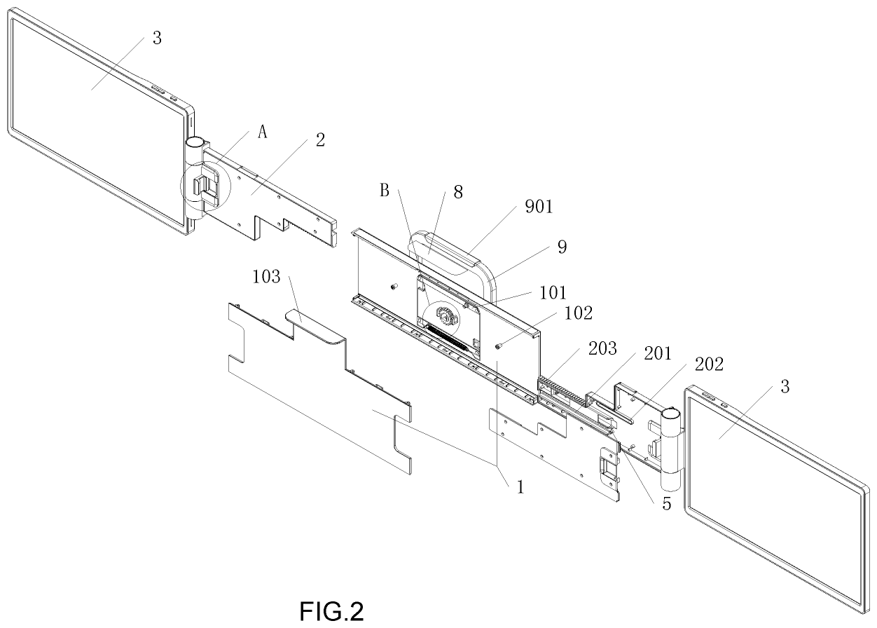

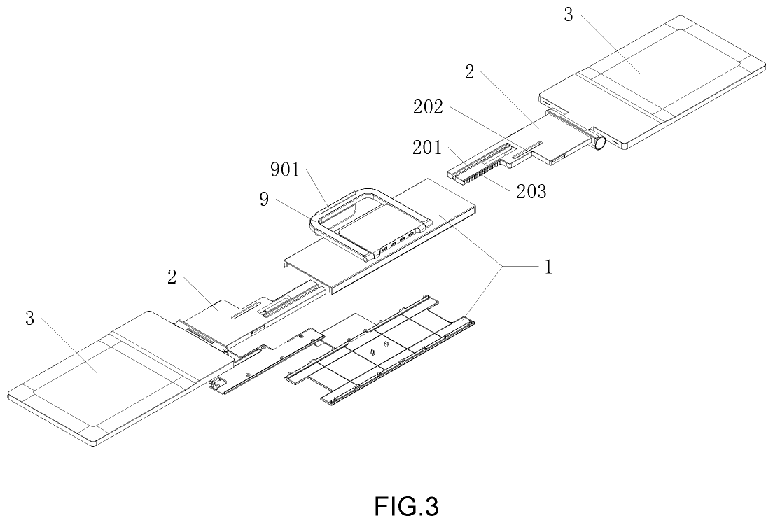

As shown in FIG. 2 and FIG. 3, in a preferred embodiment, sliding rails 101 are arranged on the fixed member 1, a sliding groove 201 slidably connected to one of the sliding rails 101 is formed in each of the movable members 2, positioning columns 5 are arranged in the sliding rail 101 and the sliding groove 201 respectively, a spring 6 is arranged between the two positioning columns 5, and two ends of the spring 6 are connected to the two positioning columns 5 respectively. When the movable members 2 telescope in the fixed member 1, the sliding rails 101 slide relative to the sliding grooves 201 to limit the fixed member 1 and the movable members 2, so that the movable members 2 are more stable during telescoping. When the movable members 2 are pulled to extend out, the springs 6 are stretched, after the clamping portions 4 clamp the main display screen, the movable members 2 are loosened, and under the action of the elasticity of the springs 6, the two movable members 2 get close to each other to make clamping firmer. After usage and after the two movable members 2 are loosened from the main display screen, under the action of the elasticity of the springs 6, the two movable members 2 are automatically retracted into the fixed member 1, thereby facilitating storage.

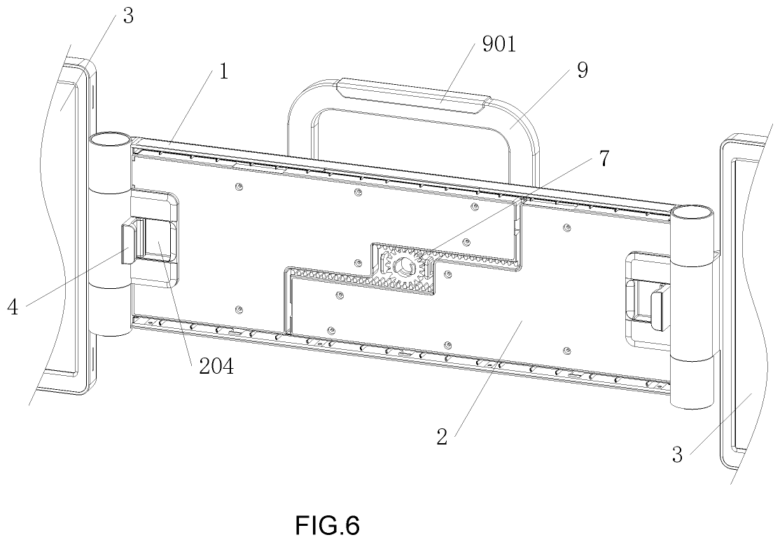

As shown in FIG. 2, FIG. 3, FIG. 6 and FIG. 8, in a preferred embodiment, limiting columns 102 are arranged on the fixed member 1, limiting grooves 202 slidably connected to the limiting columns 102 are formed in the movable members 2, and the length of the limiting grooves 202 is the telescopic stroke of the movable members 2. When the movable members 2 slide relative to the fixed member 1, the limiting columns 102 slide in the limiting grooves 202 to assist the sliding rails 101 and the sliding groove 201 to limit the movable members 2 and the fixed member 1; and when the limiting columns 102 move to ends of the limiting grooves 202, the movable members 2 are limited such that they cannot be stretched or retracted continuously, thereby controlling the telescopic stroke of the movable members 2, and preventing the movable members 2 from being separated from the fixed member 1 or preventing the two movable members 2 from colliding. A gear 7 is rotatably connected to the fixed member 1, racks 203 meshing with the gear 7 are arranged on the movable members 2, the first ends of the movable members 2 are step-shaped, and the first ends of the two movable members 2 are staggered with each other. One gear 7 mesh with the racks 203 on the two movable members 2 such that the two movable members 2 telescope synchronously; and the transmission precision between the gear 7 and the racks 203 is high, which ensures the telescoping synchronism between the two movable members 2. The first ends of the movable members 2 are step-shaped such that the opposite sides of the two movable members 2 are staggered with each other, thereby preventing the two movable members 2 from interfering mutually during retraction. The middle of the gear 7 is hollow, a fastener is arranged on the fixed member 1, the fastener is clamped in the middle of the gear 7, the gear 7 can rotate around the fastener, and thus mounting and dismounting of the gear 7 are facilitated. The two movable members 2 are in transmission connection by means of the gear 7, then the two movable members 2 can be pulled by one spring 6, and two springs 6 can be provided if the large clamping force is required.

The auxiliary display screens 3 are hinged to the movable members 2, and damping members are arranged at the hinged positions. The auxiliary display screens 3 can rotate relative to the movable members 2 by means of hinging, thereby facilitating adjustment; the rotation resistance between the auxiliary display screens 3 and the movable members 2 is increased by the damping members, and after the auxiliary display screens 3 are rotatably adjusted to proper angles, the auxiliary display screens can be suspended at those angles and are not prone to change, thereby facilitating usage; and during storage, the folded state is kept, and the auxiliary display screens are not prone to unfolding, thereby facilitating storage.

As shown in FIG. 2, in a preferred embodiment, a clamping plate 103 is arranged at the top of the fixed member 1. Pads 8 are arranged on the sides of the clamping plate 103 and the clamping portions 4 that are in contact with the main display screen. When the screen splitter is connected to the main display screen, the clamping plate 103 is in contact with the top of the main display screen to assisting in supporting the screen splitter, thereby preventing the screen splitter from sliding off from the main display screen, and improving the connection stability of the screen splitter and the main display screen. By means of the pads 8, when the clamping plate 103 and the clamping portions 4 are in contact with the main display screen, the main display screen can be protected, thereby preventing the main display screen from being damaged during connection; and the pads may be made of flexible materials having rough surfaces, for example, rubber, silica gel, etc., thereby increasing the friction force between the main display screen and the screen splitter, and further improving the connection stability.

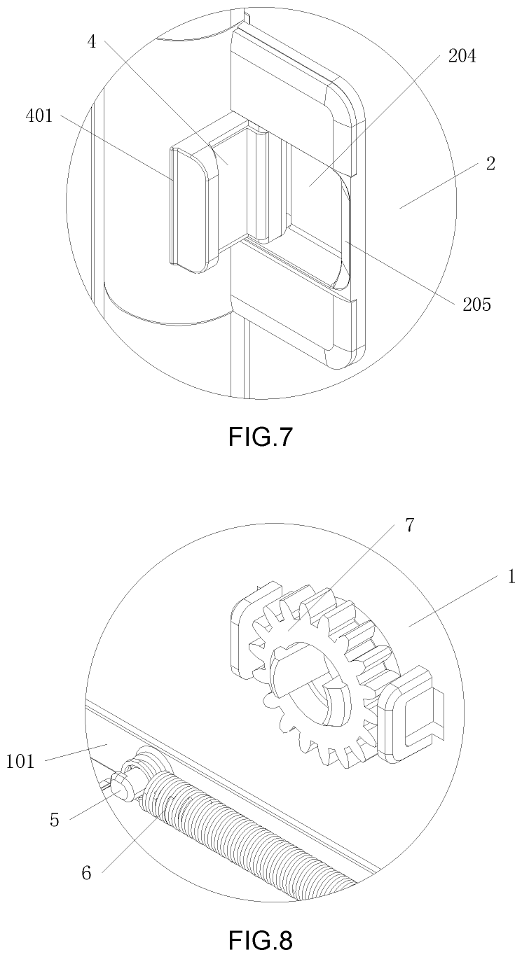

As shown in FIG. 7, in a preferred embodiment, holding grooves 204 are formed in the movable members 2, the clamping portions 4 are hinged to the holding grooves 204, and the clamping portions 4 are rotatably stored in the holding grooves 204 or rotatably protrude out of the holding grooves 204. When the screen splitter is in use, the clamping portions 4 are rotated to protrude out of the holding grooves 204 such that the clamping portions 4 can be clamped with side surfaces of the main display screen in a contact manner; and when the screen splitter is not in use, the clamping portions 4 are rotated to be stored in the holding grooves 204, thereby facilitating storage. Avoiding openings 205 are formed at the positions of groove openings of the holding grooves 204 that are far away from the hinged positions with the clamping portions 4, and ribs 401 are arranged at the positions of the clamping portions 4 that are close to the avoiding openings 205. By means of the avoiding openings 205, when the clamping portions 4 are rotated out of the holding grooves 204, hands can make contact with the clamping portions 4 in the holding grooves 204 conveniently, so that the clamping portions 4 can be rotated out conveniently; and the ribs 401 are arranged at the clamping portions 4 to increase the roughness degree of the surfaces of the clamping portions 4, then to increase the friction force between the hands and the clamping portions 4, and to further facilitate rotating the clamping portions 4 out of the holding grooves 204.

As shown in FIG. 5, in a preferred embodiment, a U-shaped support 9 is hinged to the back of the fixed member 1. A sheath 901 is arranged on the outer side of the top of the U-shaped support 9, a damping member is also arranged at the hinged position, and the damping member is configured to increase the rotation resistance. The U-shaped support 9 is arranged at the back of the fixed member 1, when in use, devices such as personal digital assistants and mobile phones which need auxiliary supporting for standing can be supported by the U-shaped support 9, and the U-shaped support 9 can support the devices such as the personal digital assistants and the like after being rotated by a certain angle; and the rotation resistance between the U-shaped support 9 and the fixed member is increased by the damping member such that it is not easy for the two to rotate relatively, the angle after adjustment can be kept, and usage is facilitated. During supporting, the friction force between the U-shaped support 9 and a supporting table top can be increased by means of the sheath 901, thereby improving the supporting stability. In addition, the U-shaped support 9 can be used for suspending and fixing, which further improves the stability of the connected screen splitter. When the screen splitter is not in use, carrying by hand is facilitated by the U-shaped support 9, thereby facilitating carrying and handling; and the sheath 901 can protect hands of a person during handling.

As shown in FIG. 3, in a preferred embodiment, at least one expansion interface is provided on the fixed member 1, and the expansion interfaces are configured to be externally connected to display screens. There are two expansion interfaces on the fixed member 1, the fixed member 1 can be connected to two extra external display screens by means of the two expansion interfaces, and four split screens can be achieved through combination with the two unfolded auxiliary display screens 3. When multi-screen display is used, the power supply to the computer is generally insufficient when more than two split screens are used, and sufficient power for the device having the more than two split screens can be guaranteed by providing the expansion interfaces on the fixed member 1.

In a preferred embodiment, lines of the auxiliary display screens 3 are gathered in a bus, and an interface of the bus is provided on the fixed member 1, so that the lines of the auxiliary display screens 3 are gathered in one interface, the lines are simplified, wiring by the user is facilitated, and usage by the user is facilitated; and in addition, the lines and the bus are hidden in the fixed member 1, thereby avoiding twining during usage, facilitating usage and achieving beauty.

The above are only the preferred embodiments of the present invention, and do not limit the present invention. Any modification, equivalent replacement and improvement made within the spirit and principles of the present invention should fall within the scope of protection of the present invention.

What is claimed is:

1. A screen splitter capable of realizing equal stretching and clamping, comprising a fixed member, wherein movable members are arranged on two sides of the fixed member respectively, a second end of at least one of the movable members is rotatably connected to an auxiliary display screen, clamping portions are arranged at the second ends on the front sides of the movable members, first ends of the movable members are arranged in the fixed member and are telescopically connected to the fixed member, and the two movable members telescope on the fixed member so as to adjust the distance between the two clamping portions such that main display screens of different sizes can be clamped by the two clamping portions.

2. The screen splitter according to claim 1, wherein sliding rails are arranged on the fixed member, a sliding groove slidably connected to one of the sliding rails is formed in each of the movable members, positioning columns are arranged in the sliding rail and the sliding groove respectively, a spring is arranged between the two positioning columns, and two ends of the spring are connected to the two positioning columns respectively.

3. The screen splitter according to claim 1, wherein limiting columns are arranged on the fixed member, limiting grooves slidably connected to the limiting columns are formed in the movable members, and the length of the limiting grooves is the telescopic stroke of the movable members.

4. The screen splitter according to claim 1, wherein a gear is rotatably connected to the fixed member, racks meshing with the gear are arranged on the movable members, the first ends of the movable members are step-shaped, and the first ends of the two movable members are staggered with each other.

5. The screen splitter according to claim 1, wherein a clamping plate is arranged at the top of the fixed member.

6. The screen splitter according to claim 1, wherein holding grooves are formed in the movable members, the clamping portions are hinged to the holding grooves, and the clamping portions are rotatably stored in the holding grooves or rotatably protrude out of the holding grooves.

7. The screen splitter according to claim 6, wherein avoiding openings are formed at the positions of groove openings of the holding grooves that are far away from the hinged positions with the clamping portions, and ribs are arranged at the positions of the clamping portions that are close to the avoiding openings.

8. The screen splitter according to claim 1, wherein a support is rotatably connected to the back of the fixed member, and the support is rotatably unfolded to support the fixed member.

9. The screen splitter according to claim 1, wherein at least one expansion interface is provided on the fixed member, and the expansion interfaces are configured to be externally connected to display screens.

10. The screen splitter according to claim 1, wherein lines of the auxiliary display screens are gathered in a bus, the lines and the bus are hidden in the fixed member, and an interface of the bus is provided on the fixed member.
